(19) United States
(12) Patent Application Publication
(10) Pub. No.: US 2002/0113281 A1
(43) Pub. Date: Aug. 22, 2002

(54) MEMS device having an actuator with curved electrodes

(76) Inventors: Shawn Jay Cunningham, Colorado Springs, CO (US); Dana R. DeReus, Colorado Springs, CO (US)

Correspondence Address: JENKINS & WILSON, PA, 3100 TOWER BLVD, SUITE 1400, DURHAM, NC, 27707, US

(21) Appl. No.: 10/025,974

(22) Filed: Dec. 19, 2001

Related U.S. Application Data
(60) Provisional application No. 60/256,683, filed on Dec. 19, 2000.
(60) Provisional application No. 60/256,604, filed on Dec. 19, 2000.
(60) Provisional application No. 60/256,607, filed on Dec. 19, 2000.
(60) Provisional application No. 60/256,610, filed on Dec. 19, 2000.
(60) Provisional application No. 60/256,611, filed on Dec. 19, 2000.
(60) Provisional application No. 60/256,674, filed on Dec. 20, 2000.
(60) Provisional application No. 60/256,688, filed on Dec. 19, 2000.
(60) Provisional application No. 60/256,689, filed on Dec. 19, 2000.
(60) Provisional application No. 60/260,558, filed on Jan. 9, 2001.

(51) Int. Cl. H01L 29/82

(52) U.S. Cl. 257/415; 257/417; 257/418; 257/419

(57) ABSTRACT

MEMS Device having an Actuator with Curved Electrodes. According to one embodiment of the present invention, an actuator is provided for moving an actuating device linearly. The actuator includes a substrate having a planar surface and an actuating device movable in a linear direction relative to the substrate. The actuator includes at least one electrode beam attached to the actuating device and having an end attached to the substrate. The electrode beam is flexible between the actuating device and the end of the electrode beam attached to the substrate. Furthermore, the actuator includes at least one electrode attached to the substrate. The electrode has a curved surface aligned in a position adjacent the length of the electrode beam, whereby the actuating device is movable in its substantially linear direction as the electrode beam moves in a curved fashion corresponding substantially to the curved surface of the electrode.

### CROSS-REFERENCE TO RELATED APPLICATION

This nonprovisional application claims the benefit of U.S. Provisional Application No. 60/256,683, filed Dec. 19, 2000, U.S. Provisional Application No. 60/256,604, filed Dec. 19, 2000, U.S. Provisional Application No. 60/256,607, filed Dec. 19, 2000, U.S. Provisional Application No. 60/256,610, filed Dec. 19, 2000, U.S. Provisional Application No. 60/256,611, filed Dec. 19, 2000, U.S. Provisional Application No. 60/256,674, filed Dec. 20, 2000, U.S. Provisional Application No. 60/256,688, filed Dec. 19, 2000, U.S. Provisional Application No. 60/256,689, filed Dec. 19, 2000, and U.S. Provisional Application No. 60/260,558, filed Jan. 9, 2001, the disclosures of which are incorporated by reference herein in their entirety.

### TECHNICAL FIELD

The present invention relates to micro-electro-mechanical systems (MEMS) devices having actuators. More particularly, the present invention relates to optical MEMS devices having actuators that employ electrostatic energy mechanisms for moving an actuating device linearly.

### BACKGROUND ART

In communication networks, optical transmission systems are often used for the transmission of data signals between network terminals such as telephones or computers. Optical transmission systems transmit data signals via data-encoded light through fiber optics. Many functions in optical switching systems require the movement of an actuating device in order to interact with the light output from “incoming” fiber optics. Among the functions requiring light interaction are redirecting light from one fiber optic to another, shuttering light, filtering light, and converting light output to electrical form.

In order to perform optical switching system functions, small machines, known as micro-electro-mechanical systems (MEMS) devices, are typically used to interact with transmitted light. MEMS is a technology that exploits lithographic mass fabrication techniques of the kind that are used by the semiconductor industry in the manufacture of silicon integrated circuits. Generally, the technology involves shaping a multilayer structure by sequentially depositing and shaping layers of a multilayer wafer that typically includes a plurality of polysilicon layers that are separated by layers of silicon oxide and silicon nitride. Typically, individual layers are shaped by a process known as etching. The etching process is generally controlled by masks that are patterned by photolithographic techniques. MEMS technology can involve the etching of intermediate sacrificial layers of the wafer to release overlying layers for use as thin elements that can be easily deformed or moved to function as an actuator.

An actuating device is any MEMS device component that is movable with respect to a substrate on which the MEMS device is attached due to forces generated by the MEMS device. Oftentimes, MEMS devices in optical switching systems interact with light by moving an actuating device, such as a shutter, in and out of a light pathway for blocking, filtering or reflecting transmitted light. Some of the most common and widely used means employed by MEMS devices for generating a force on an actuating device consist of electrostatic, thermal (including shape memory alloys), and magnetic energy mechanisms. Typically, MEMS devices employing thermal or magnetic energy mechanisms have higher power consumption for generating the same forces as those employing electrostatic energy mechanisms.

Electrostatic actuation operates on the principle of Coulomb's law that two conductors with equal and opposite charge will generate an attractive force between them. Electrostatic actuation is generally implemented by applying a voltage potential between a fixed and movable electrode. This difference in voltage potential generates an equal and opposite charge on the fixed and movable electrode which causes movement of the movable electrode towards the fixed electrode.

MEMS devices employing electrostatic actuation move actuating devices in a curvilinear or linear direction depending on the type of MEMS device. In most applications, an array of MEMS devices employing linear motion can be more densely packaged on a substrate than MEMS devices employing curvilinear motion. However, MEMS devices employing linear motion typically have greater power requirements than those MEMS devices employing curvilinear motion. Furthermore, actuating device displacement ranges are typically lower for MEMS device employing linear motion.

Therefore, it is desirable to improve the packaging density of optical MEMS devices fabricated on a substrate by providing linear motion to a MEMS device employing linear motion. It is also desirable to provide a MEMS device having low power requirements. Furthermore, it is desirable to provide a MEMS device having high actuating device displacement ranges.

### DISCLOSURE OF THE INVENTION

According to one aspect of the present invention, an actuator is provided that includes a substrate having a substantially planar surface and an actuating device movable in a substantially linear direction relative to the substrate. The actuator includes at least one bendable electrode beam attached to the actuating device and having an end attached to the substrate. The electrode beam is flexible between the actuating device and the end of the electrode beam attached to the substrate. Furthermore, the actuator includes at least one electrode attached to the substrate. The electrode has a curved surface aligned in a position adjacent the length of the electrode beam, whereby the actuating device is movable in its substantially linear direction as the electrode beam moves in a curved fashion corresponding substantially to the curved surface of the electrode.

According to a second aspect of the present invention, a method is provided for moving an actuating device in a linear direction. The method includes providing a substrate having a substantially planar surface and providing an actuating device movable in a substantially linear direction relative to the substrate. The method also includes providing at least one bendable beam attached to the actuating device and having an end attached to the substrate. The electrode beam is flexible between the actuating device and the end of the electrode beam attached to the substrate. Furthermore, the method includes providing at least one electrode attached to the substrate. The electrode has a curved surface aligned in a position adjacent the length of the electrode beam. Additionally, the method includes applying a voltage across the electrode beam and curved electrode to move the electrode beam in a curved fashion corresponding to the curved surface of the electrode, whereby the actuating device moves in a substantially linear direction.

Accordingly, it is an object of the present invention to provide an actuator to provide linear motion to an actuating device.

It is another object of the present invention to provide an actuator having low power requirements.

Some of the objects of the invention having been stated hereinabove and which are achieved in whole or in part by the present invention, other objects will become evident as the description proceeds when taken in connection with the accompanying drawings as best described hereinbelow.

### BRIEF DESCRIPTION OF THE DRAWINGS

Exemplary embodiments of the invention will now be explained with reference to the accompanying drawings, of which:

FIG. 1 is a schematic view of an electrostatic comb-drive type MEMS device for providing motion to an actuating device in a linear direction parallel to the plane of a substrate surface;

FIG. 2 is a schematic view of an electrostatic, curved electrode actuator type MEMS device for moving an actuating device in a curved direction parallel to the plane of a substrate surface;

FIG. 3 is a schematic view of an optical MEMS device having an actuating device for linear motion according to an embodiment of the present invention;

FIG. 4 is a schematic view of an optical MEMS device in an active state in which a shutter is positioned outside of a light pathway;

FIG. 5 is a schematic view of a two-fold flexure attached to an electrode beam and a frame;

FIG. 6 is a schematic view of a one-fold flexure for attaching an electrode beam to a frame;

FIG. 7 is a schematic view of a crab leg flexure for attaching an electrode beam to a frame;

FIG. 8 is a diagram illustrating an actuator model for use in computer-aided design (CAD) electromechanical simulations of movement of an electrode beam in accordance with an embodiment of the present invention;

FIG. 9 is a diagram illustrating CAD simulation results as a function of curved surface gap distance and voltage for a one-fold flexure design;

FIG. 10 is a diagram illustrating CAD simulation results as a function of curved surface gap distance and voltage for a two-fold flexure design;

FIG. 11 a schematic view of a bidirectional actuator for an optical MEMS device according to another embodiment of the present invention;

FIG. 12 a schematic view of an optical MEMS device having a shutter attached to two actuator pairs according to another embodiment of the present invention;

FIG. 13 a schematic view of a two-stage mode actuator for an optical MEMS device according to an embodiment of the present invention;

FIG. 14 a schematic view of a two-stage mode actuator positioned at the end of the first stage of actuation;

FIG. 15 a schematic view of a two-stage mode actuator positioned at the end of the second stage of actuation;

FIG. 16 a schematic view of another embodiment of a MEMS device for moving a shutter in accordance with the present invention;

FIG. 17 a schematic view of a set of light pathways extending perpendicular to a substrate and a set of bidirectional actuators;

FIG. 18 a schematic view of another set of light pathways extending perpendicular to a substrate and a set of unidirectional, two-stage actuators; and

FIG. 19 a schematic view of another set of light pathways and a set of frame, bidirectional actuators.

### DETAILED DESCRIPTION OF THE INVENTION

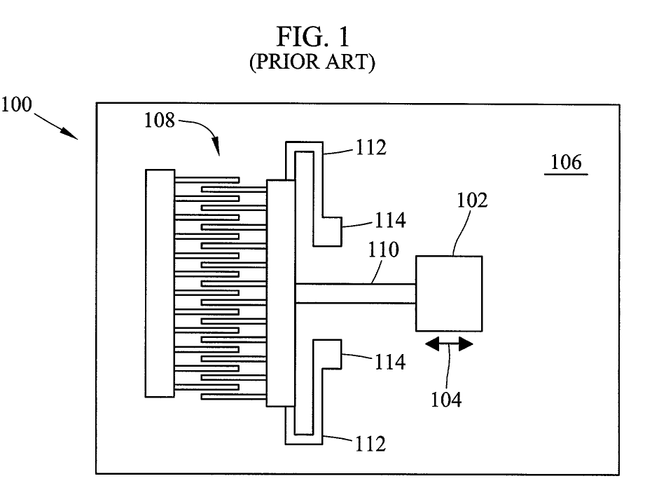

The present invention has many advantages apparent to those of skill in the art over known type MEMS devices employing electrostatic actuation. One known type MEMS device employing electrostatic actuation for providing linear motion is an electrostatic comb-drive type MEMS device. Referring to FIG. 1, a schematic view of an electrostatic comb-drive type MEMS device 100 is illustrated for providing motion to an actuating device 102 in a linear direction (indicated by direction arrows 104) parallel to the plane of substrate surface 106. Linear motion is provided by applying a voltage across fixed combs generally designated 108. This generates a force on a movable arm 110, thereby moving actuating device 102. Movable arm 110 is attached to substrate surface 106 via a spring 112 and an anchor 114. Spring 112 allows movable arm 110 to have motion with respect to substrate surface 106. As compared to MEMS device 100, the present invention is typically able to produce larger forces and actuating device displacement for comparable applied voltages and size.

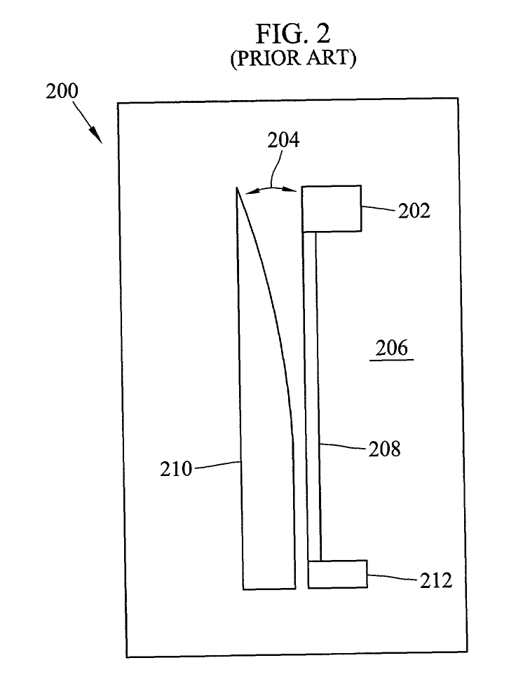

Another MEMS device employing electrostatic actuation known to those of skill in the art is a curved electrode type MEMS device. This MEMS device provides an actuating device with curvilinear motion. Referring to FIG. 2, a schematic view of an electrostatic, curved electrode actuator type MEMS device 200 is illustrated for moving an actuating device 202 in a curved direction (indicated by direction arrows 204) parallel to the plane of a substrate surface 206. MEMS device 200 is attached to substrate surface 206. MEMS device 200 includes a bendable electrode beam 208, a curved electrode 210 attached to substrate surface 206, and an anchor 212 attached to substrate surface 206. On the application of a voltage across curved electrode 208 and electrode beam 210, MEMS device 200 moves actuating device 202 in a curved direction towards curved electrode 210. As stated above, MEMS devices employing curvilinear motion cannot be packaged as densely in an array as MEMS devices employing linear motion.

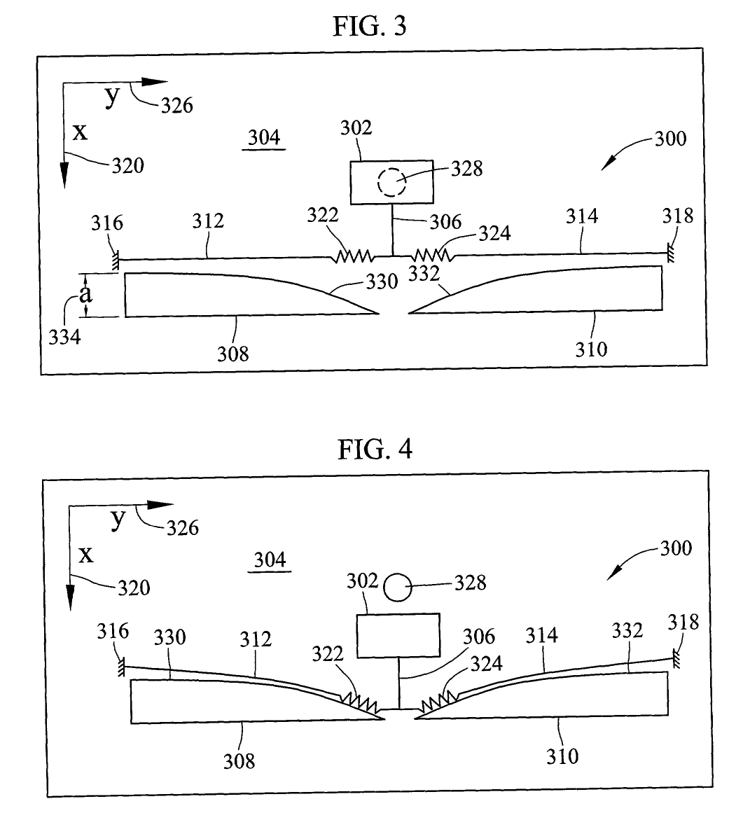

In accordance with one embodiment of the present invention, a MEMS device having actuators is provided for providing linear motion to an actuating device. Referring to FIG. 3, a schematic view of an optical MEMS device generally designated 300 having an actuating device, a shutter 302 in this example, for linear motion according to an embodiment of the present invention is provided. MEMS device 300 and shutter 302 are fabricated onto a substrate surface 304 and attached together via a frame 306 of shutter 302. MEMS device 300 includes electrodes 308 and 310, electrode beams 312 and 314, and anchors 316 and 318. Frame 306 is attached to substrate surface 304 via a flexible portion 322 and 324, electrode beams 312 and 314, and anchors 316 and 318.

Shutter 302 and frame 306, combined, form an actuating device which is provided relative movement with respect to substrate surface 304 in a linear direction x 320 on the application of a voltage across electrode beams 312 and 314 and electrodes 308 and 310, respectively. In this embodiment, shutter 302 functions to interact with light. In an alternate embodiment, another suitable actuating device known to those of skill in the art can be attached to electrode beams 312 and 314 for providing movement in a linear direction. For example, the MEMS device of the present invention can have an actuating device adapted for use as a DC microswitch/microrelay, an RF microswitch, a fluidic switch, a variable optical attenuator, an infrared detector, a electromechanical latch actuator, an actuator to drive the push pawl and drive pawl in stepper motor applications, a linear stepper motor, a driver in a linear impact motor, a linear actuator in a microimpact tester, a linear actuator to drive pop up mirrors, gratings, various other micro-components, components requiring out-of-plane movement, a self testable accelerometer, a variable capacitor, and other such micro-components requiring motion.

Voltage can be provided by any suitable voltage source for providing a voltage across electrode beams 312 and 314 and electrodes 308 and 310, respectively, as described below. As shown in FIG. 3, MEMS device 300 is in its inactive state and position, wherein no voltage is applied across electrode beams 312 and 314 and electrodes 308 and 310, respectively.

MEMS device 300 is unidirectional, meaning motion is provided in only one direction from its position in an inactive state (as shown). Shutter 302 and frame 306 move in a direction x 320 in a plane (the plane formed by direction arrows x 320 and y 326) parallel to substrate surface 304. Motion is provided on the application of a voltage across electrode beams 312 and 314 and electrodes 308 and 310, respectively, which thereby produces an attractive force between electrode beams 312 and 314 and electrodes 308 and 310, respectively. At a threshold voltage the attractive force is great enough to pull in each electrode beam 312 and 314 adjacent its corresponding electrode 308 and 310, respectively. Similarly, on the removal of a voltage across electrode beams 312 and 314 and its corresponding electrode 308 and 310, respectively, shutter 302 and frame 306 will move in a direction opposite direction x 320.

In another embodiment, the analytic function describing the shape of surfaces 330 and 332 of electrodes 308 and 310, respectively, can be modified to produce a continuous monotonic motion of shutter 302 and frame 306. The motion begins with an abrupt motion and then the motion is continuous as beams 312 and 314 increasingly establish greater contact with surfaces 330 and 332 of electrodes 308 and 310, respectively. With these two embodiments, two different motions can be established with the present patent. The first motion has two stable states: “Open”/“Closed”, “On”/“Off”, “Unobstructed”/“Obstructed”. The second motion has many stable states that define the continuous motion of shutter 302 and allow variable attenuations of a light signal.

In this embodiment, light is transmitted along a light pathway 328 (shown as broken lines) perpendicular to substrate surface 304. In operation, shutter 302 can be moved from a position intercepting light pathway 328 (as shown) to a position outside light pathway 328. Referring to FIG. 4, a schematic view of an optical MEMS device 300 is illustrated in an active state in which shutter 302 is positioned outside of light pathway 328. In the active state, voltage has been applied across electrode beams 312 and 314 and its corresponding electrode 308 and 310, respectively, causing frame 306 to move in a linear direction x 320. When the applied voltage is removed or reduced sufficiently, the elastic restoring force of electrode beams 312 and 314 returns them to a shape and position as shown in FIG. 3.

Shutter 302 in this embodiment is preferably made of a material that does not transmit light. Non-limiting examples of optically non-transmissible materials include silicon with a gold (Au) or Aluminum (Al) film or other suitable materials known to those of skill in the art. Alternatively, shutter 302 can be made of a transmissible material including the non-limiting examples glass, quartz, and sapphire. In each case, the transmissibility is determined by the material and the wavelength of light.

Substrate surface 304 is composed of an electrically insulated material such as Gallium Arsenic (GaAs) substrate, a glass substrate, an oxidized silicon wafer or a printed circuit board (PCB). In this embodiment, the substrate is transmissible to light, thus, allowing for light transmission along light pathway 328 through the substrate. The transmissibility can be associated with the material and the wavelength of the incident light or it can be associated with an optical aperture through substrate 304. In the case of the transmissible material, the transmission efficiency can be improved be the addition of an antireflective coating on surface 304.

Electrode beams 312 and 314 are each connected at one end to anchors 316 and 318, respectively. At a distal end, electrode beams 312 and 314 are connected to frame 306. Flexible portions 322 and 324 represent the natural flexibility of electrode beams 312 and 314, respectively. This flexibility serves to translate the curvilinear motion of the ends of electrode beams 312 and 314 connected to frame 306 into a linear motion. In some instances, electrode beams 312 and 314 can buckle due to excessive residual stress due to the fabrication process, temperature, or other stressors. Therefore, in an alternate embodiment, flexures can be included with electrode beams 312 and 314 to relieve residual stress and prevent buckling.

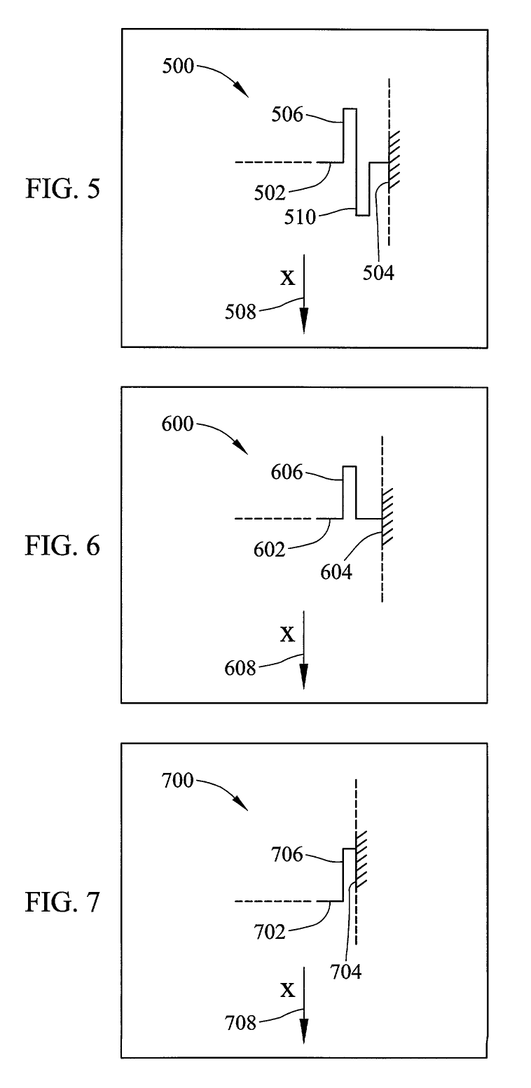

Flexures can be integrated with an electrode beam at one end for attachment to a frame. In alternative embodiments of the present invention, a flexure can be a compliant hinge, compliant joint, spring, coil spring, or any other suitable flexure known to those of skill in the art. Referring now to FIG. 5, a schematic view of a two-fold flexure 500 attached to an electrode beam 502 and a frame 504 is illustrated. In one embodiment, two-fold flexure generally designated 500 is manufactured of the same piece of material as electrode beam 502. Alternatively, flexure can be made of a different piece of material. The piece of material is formed into a shape having a fold 506 in one direction x 508 and another fold 510 in a direction opposite direction x 508. Folds 506 and 510 serve as a pivot conducive for translating movement of the electrode beam 502 into direction x 508. Furthermore, flexure 500 can translate movement of electrode beam 502 into a direction opposite direction x 508.

In another embodiment, a one-fold flexure can be used for attaching an electrode beam to a frame. Referring now to FIG. 6, a schematic view of a one-fold flexure generally designated 600 for attaching an electrode beam 602 to a frame 604 is illustrated. In one embodiment, one-fold flexure 600 is manufactured of the same piece of material as electrode beam 602. The piece of material is formed into a shape having a fold 606 in direction x 608. Fold 606 serves as a pivot conducive for movement of frame 604 in direction x 608 at the point of attachment of electrode beam 602 and frame 604.

In yet another embodiment, a crab leg flexure can be used for connecting electrode beams 312 and 314 to frame 306 (as shown in FIGS. 3 and 4). Referring now to FIG. 7, a schematic view of a crab leg flexure generally designated 700 for attaching an electrode beam 702 to a frame 704 is illustrated. In one embodiment, crab leg flexure 700 is manufactured of the same piece of material as electrode beam 702. The piece of material is formed into a shape having a half fold 706 in direction x 708. Frame 704 is attached at half fold 706. Half fold 706 serves as a pivot conducive for movement of frame 704 in direction x 708 at the point of attachment of electrode beam 702 and frame 704.

Referring again to FIG. 3, as mentioned above actuator 300 is shown in an inactive state because voltage is not applied across either electrode beam 312 and electrode 308 or electrode beam 314 and electrode 310. Therefore, electrode beams 312 and 314 are shaped in their natural position, a substantially straight line, because they are not attracted to either electrodes 308 and 310. As a result, electrode beams 312 and 314 are not bent towards either electrode 308 or electrode 310.

Electrodes 308 and 310 are positioned in a direction x 320 with respect to electrode beams 312 and 314 for attracting electrode beams 312 and 314 in direction x 320 on the application of voltage. Electrodes 308 and 310 have convex, curved surfaces 330 and 332 adjacent to and facing electrode beams 312 and 314. Curved surfaces 330 and 332 each extend a distance a 334 in direction x 320.

Each electrode beam 312 and 314 extends a length from a first end (connected to anchors 316 and 318, respectively) to a second end connected by flexible portions 322 and 324, respectively, to frame 306. In this embodiment, each electrode beam 312 and 314 has a bendable portion extending substantially the entire length from the first end to the second end. Alternatively, the bendable portion can only extend a portion of the length of electrode beam or several different portions.

As shown, each electrode beam 312 and 314 is closest to curved surfaces 330 and 332, respectively, at a point on its length furthest from frame 306. When a voltage is applied across electrodes 312 and 314 and electrode beams 312 and 314, respectively, this point furthest from frame 306 is where the attractive force is greatest. On the application of a threshold voltage, electrode beams 312 and 314 will begin to bend at this point in a direction x 320 towards curved surfaces 330 and 332, respectively. Electrode beams 312 and 314 bend due the attractive force pulling them towards electrodes 312 and 314, respectively, and due to the attachment of electrode beams 312 and 314 to anchors 316 and 318, respectively.

As points of electrode beams 312 and 314 closest to curved surface 330 and 332 move closer to curved surfaces 330 and 332, respectively, adjacent points in a direction closer to frame 306 begin to move closer to curved surfaces 330 and 332. At a close enough distance to curved surface 330 and 332, a point along the length of each electrode beam 312 and 314 will be attracted with great enough force to bend electrode beam further in direction x 320. As electrode beams 312 and 314 bend closer to curved surface 312 and 314, they each form into a shape similar to the contour of curved surfaces 330 and 332. Eventually, the second end of each electrode beam 312 and 314, connected to frame 306, is displaced approximately distance a 334 to a position adjacent curved surfaces 330 and 332, respectively. This movement of electrode beams 312 and 314 serves to displace frame 306 in direction x 320 with respect to substrate surface 304.

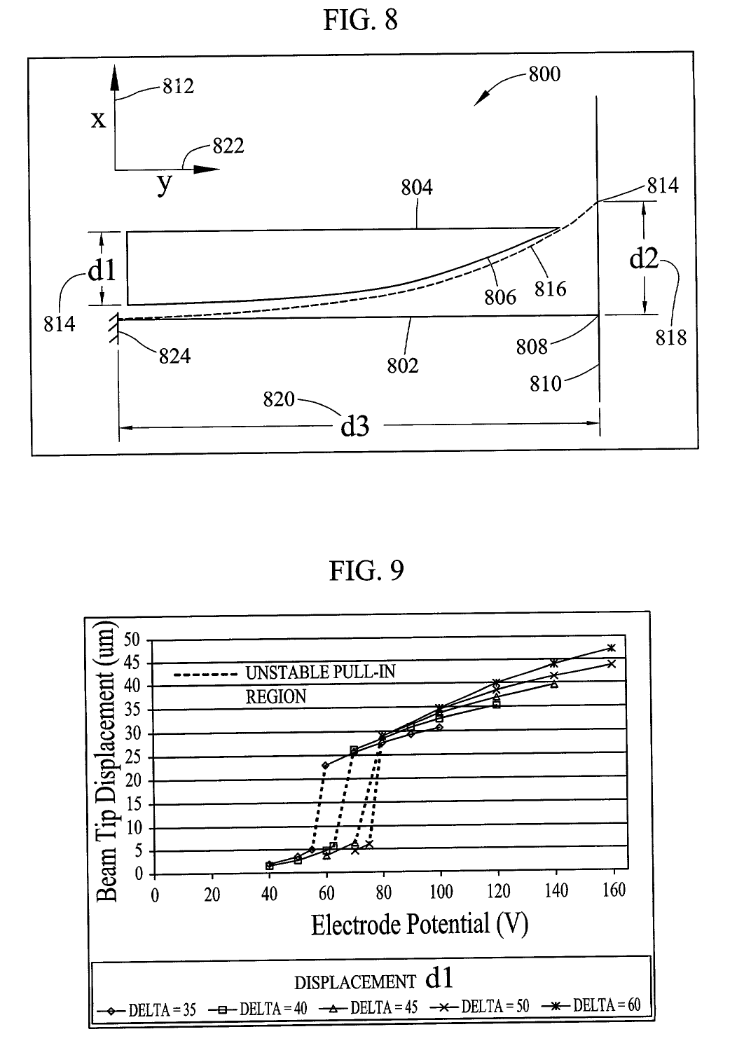

Computer-aided design (CAD) tools can be used for runnning electro-mechanical simulations of the present invention. Referring to FIG. 8, a diagram of an actuator model generally designated 800 for use in CAD electro-mechanical simulations of the movement of electrode beam 802 is illustrated in accordance with an embodiment of the present invention. An electrode 804 having a curved surface 806 and electrode beam 802 having an end 808 for attachment to a frame 810 is shown. This simulation characterizes electrode end 808 displacement in a direction x 812 as a function of the distance d1 814 that curved surface 806 extends in a direction x 812. Furthermore, displacement is characterized as a function of voltage across electrode 804 and electrode beam 802 and flexure type for attachment of end 808 to a frame (not shown). The distance of displacement of end 808 to a point of maximum displacement 814, shown by the electrode beam (shown as a broken line at reference numeral 816) in a position of maximum displacement, is a distance d2 818. Electrode beam 806 is attached to an anchor 824 at an end distal from end 808. Boundary conditions for the simulations included fixing all six degrees of freedom at anchor 824 and fixing end 808 to translate in direction x 812 and fixing the slope of end 808 to be zero in the plane of directions x 812 and y 822. Electrode beam 802 is set to zero volts and the voltage of electrode 804 was varied to generate an electrostatic attractive force between electrode beam 806 and electrode 804.

Displacement of the end of electrode beam 802 a distance d2 818 versus applied voltage across electrode 804 and electrode beam 802 is defined by a region in which displacement is not constrained by curved surface 806 and a region in which displacement is constrained by curved surface 806. Stable or unstable displacement versus voltage characteristics can be achieved in each region through various design parameters. Stable actuator performance is defined by continuous displacement versus voltage curves. Unstable actuator performance is defined by displacement versus voltage curves with discontinuous steps. Unstable actuator performance typically occurs when electrostatic force on electrode beam 802 is greater than the elastic restoring force of the deformed electrode beam 802. Generally, the greatest displacement for a given voltage can be achieved with actuators exhibiting unstable behavior.

Frame displacement versus applied voltage performance characteristics depend upon the design of the electrode beams, the design of the flexures, the curved surface of electrodes, and the initial gap distance between the electrode beam and electrode. Electrode beam compliancy is defined by the beam's cross-section, length, and material properties. The flexure spring constant is a function of the flexure cross-section, material properties, and its shape. The flexures relieve thermal and residual material stresses, and accommodate bending moments produced at the end of the beam during the active state.

The shape of an electrode's curved surface can assume many different forms. For example, the shape of a curved surface can be described by the following equation normalized to the distance the maximum distance separating the curved surface and the electrode beam (wherein di represents the maximum distance separating the electrode beam and the curved surface, x represents the position along an axis parallel to electrode beam, L represents the length of the electrode in a direction parallel to the electrode beam, and n represents the exponential order of the curve with n≧0):

$$S ( x ) = d1 * {( \frac{x}{L} )}^{n}$$

For n≧2, the actuator tends to exhibit unstable displacement versus voltage characteristics in that once the beam is first pulled-in to the electrode it will deform along the entire electrode length with the proper compliant flexure design. For n≧2, the actuator tends to exhibit stable continuous displacement versus voltage characteristics once the beam is first pulled-in to the fixed electrode.

Various electrode beam and electrode dimensions were used in the CAD simulations for the design of FIG. 8. Boundary conditions for the simulations included fixing all six degrees of freedom at anchor 824 and applying a symmetry boundary condition fixing the end 808 to translate linearly in a direction x 812. Electrode beam 802 potential voltage was set to zero volts and the electrode 804 voltage was varied to generate an electrostatic attractive force between electrode beam 802 and electrode 804.

Typical electrode beam dimensions and material properties used in the simulations are as follows: length (450 micrometers)(distance d3 820); beam thickness in direction of bending (i.e., direction x 812) (2.0 micrometers); beam width (direction perpendicular to direction x 812 and direction y 822)(3.5 micrometers); and the Young's modulus of polysilicon described by E_{poly} the Young's modulus of polysilicon described by (165 Gpa).

Typical dimensions of curved surface 806 of electrode 804 were as follows: length (440 micrometers)(distance d4 824) and maximum distance (distance d1 810)(between about 35-50 micrometers). Furthermore, a dielectric material having a thickness of 0.5 micrometers is placed on curved surface 804 to prevent shunting between electrode 802 and electrode beam 806.

Referring to FIG. 9, a diagram illustrating CAD simulation results as a function of curved surface gap distance (distance d1 814) and voltage for a one-fold flexure design is provided. The diagram shows graphs for displacement d1 814 for 35, 40,45,50,55, and 60 micrometers. Broken lines show the unstable pull-in regions. For example, a one-fold flexure with a displacement d1 of 35 micrometers has a pull-in voltage of approximately 56 volts and end displacement of 27.7 micrometers for an applied voltage of 80 volts. A crab leg flexure simulation with the same configuration as above produced pull-in voltage of approximately 60 volts with less end displacement, 26.2 micrometers.

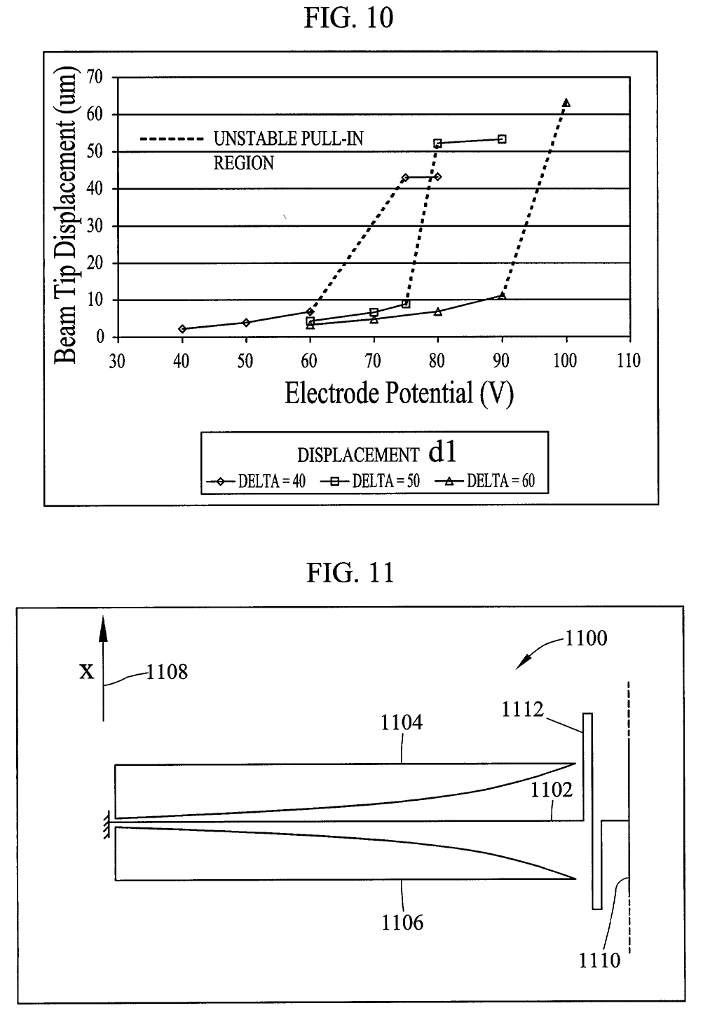

Referring to FIG. 10, a diagram illustrating CAD simulation results as a function of curved surface gap distance d1 814 and voltage for a two-fold flexure design is provided. The diagram shows graphs for displacement d1 for 40, 50, and 60 micrometers. Broken lines show the unstable pull regions. Two-fold flexures produced the best simulation results. For example, a two-fold flexure with a curved surface gap distance d1 814 of 60 micrometers produced an end displacement of 63 micrometers for an applied voltage of 100 volts. For comparison, a one-fold flexure with the same configuration produced an end displacement of approximately 35 micrometers for an applied voltage of 100 volts.

Movement of a frame from an inactive position in two directions can be achieved by placement of electrodes on opposite sides of an electrode beam. Referring to FIG. 11, a schematic view of a bidirectional actuator generally designated 1100 for an optical MEMS device according to another embodiment of the present invention is illustrated. Actuator 1100 includes an electrode beam 1102 and electrodes 1104 and 1106, each adjacent electrode beam 1102. On the application of a voltage between electrode 1104 and electrode beam 1102, electrode beam 1102 moves towards electrode 1104 causing attached frame 1110 to move in a direction x 1108. Conversely, on the application of a voltage between electrode 1106 and electrode beam 1102, electrode beam 1102 moves towards electrode 1106 causing attached frame 1110 to move in a direction opposite direction x 1108. As shown in this example, a two-fold flexure 1112 is used to attach electrode beam 1102 to frame 1110. Alternatively, any other type of flexure described above can be used.

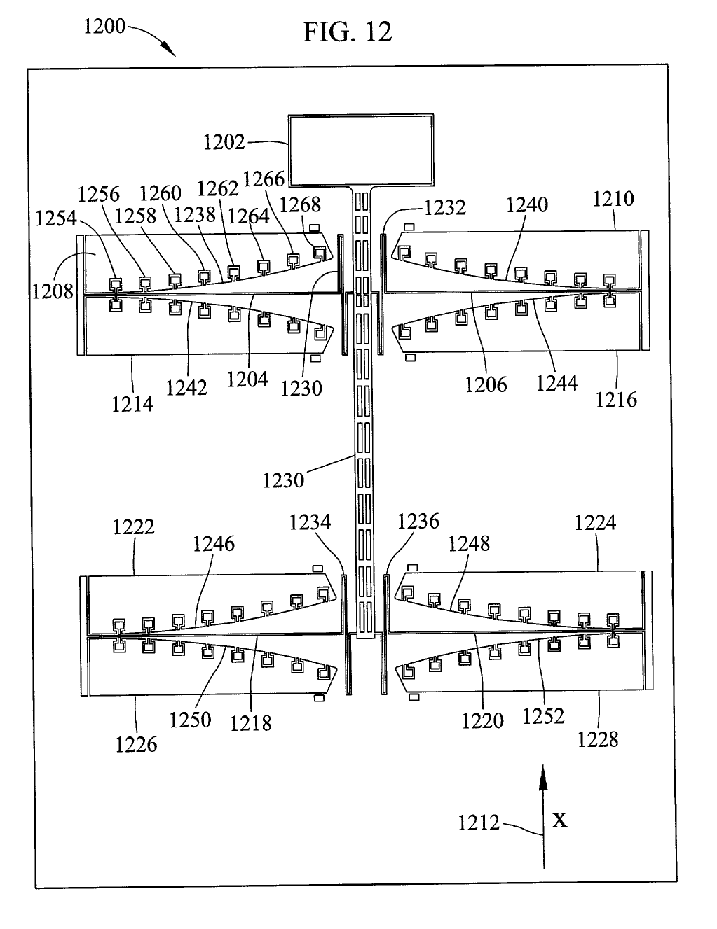

A bidirectional actuator as described above can be used along with other actuators for moving an actuating device bi-directionally. Referring to FIG. 12, a schematic view of an optical MEMS device generally designated 1200 having a shutter 1202 attached to two actuator pairs according to another embodiment of the present invention is illustrated. One actuator pair consists of electrode beams 1204 and 1206, electrodes 1208 and 1210 for movement in a direction x 1212, and electrodes 1214 and 1216 for movement in a direction opposite direction x 1212. Another actuator pair consists of electrode beams 1218 and 1220, electrodes 1222 and 1224 for movement in direction x 1212, and electrodes 1226 and 1228 for movement in a direction opposite direction x 1212. Actuator pairs function to move frame 1230 and shutter from a position in an inactive state to positions in a direction x 1212 and opposite direction x 1212. Electrode beams 1204,1206,1218, and 1220 are attached via two-fold flexures 1230,1232,1234, and 1236, respectively. Alternatively, any type of flexure or attachment described above can be used.

In this embodiment, shunting between electrodes beams 1204, 1206, 1218, and 1220 and electrodes 1208,1210,1214,1216,1222,1224,1226, and 1228 is prevented by a sets of bumpers lined along curved surfaces 1238,1240, 1242,1244,1246,1248, 1250, and 1252. For example, bumpers 1254,1256, 1258, 1260, 1262, 1264, 1266, and 1268 are positioned along curved surface 1238 between curved surface 1238 and electrode beam 1208. On the application of a voltage, electrode beam 1204 is stopped from further movement towards curved surface 1238. Bumpers 1254, 1256,1258, 1260, 1262,1264, 1266, and 1268 are made of a dielectric and can be made of any suitable non-conductive material. In another embodiment, bumpers 1254,1256,1258,1260, 1262, 1264, 1266, and 1268 can be made of a conductive material that is electrically isolated from the electrodes beams 1204, 1206, 1218, and 1220 and electrodes 1208, 1210,1214, 1216, 1222,1224,1226, and 1228.

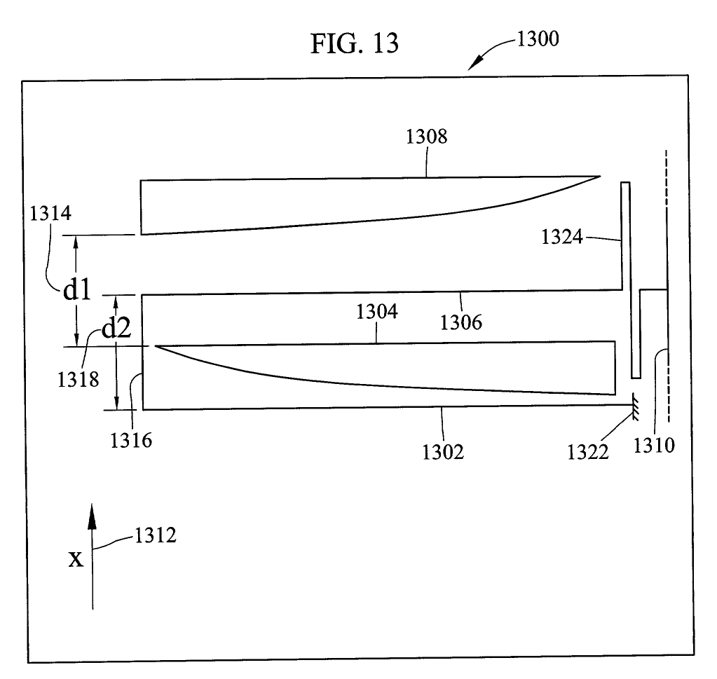

Large frame displacement in one direction can be achieved by employing a two-stage actuation design. Referring to FIG. 13, a schematic view of a two-stage mode actuator generally designated 1300 for an optical MEMS device according to another embodiment of the present invention is illustrated. Actuator 1300 includes an electrode beam 1302 corresponding to electrode 1304 and electrode beam 1306 corresponding to electrode 1308. The movement of a frame 1310 is limited to a linear direction parallel to direction x 1312. Electrodes 1304 and 1308 are separated in a direction x 1312 by a distance d1 1314. Electrode beam 1302 is attached to electrode beam 1306 via an extension arm 1316, which extends in direction x 1312 approximately a distance d2 1318. Electrode beam 1302 is attached to substrate surface 1320 via anchor 1322. Electrode beam 1306 is attached to frame 1310 via two-fold flexure 1324. Alternatively, any type of above described flexure can be used.

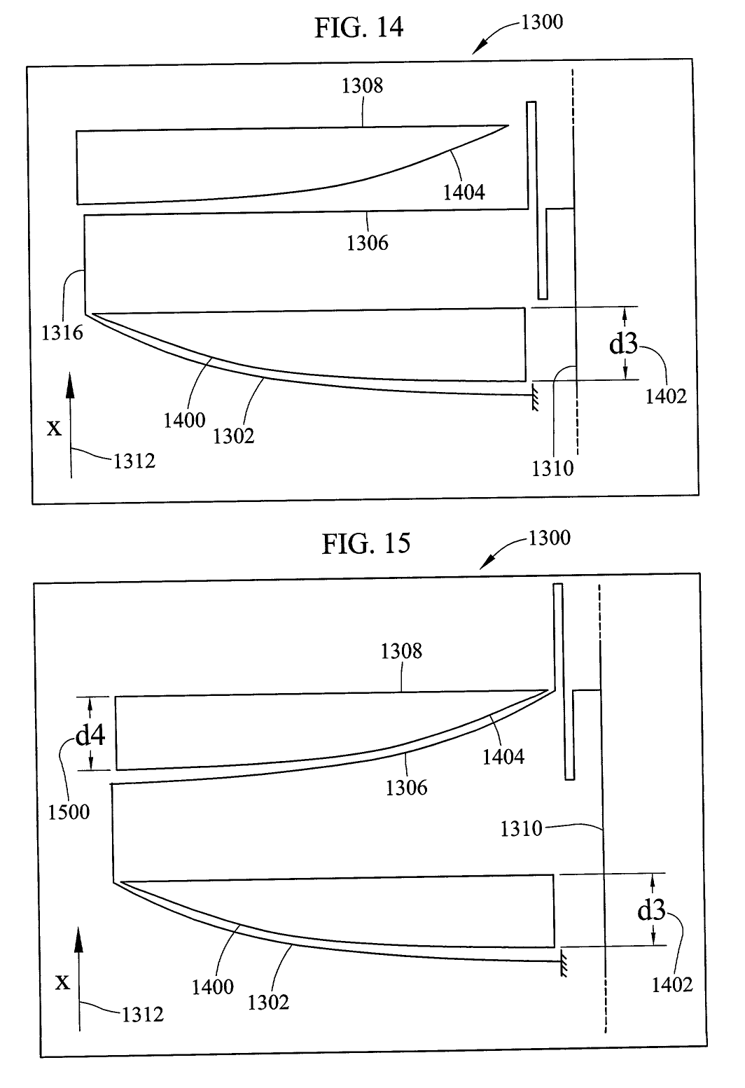

As shown in FIG. 13, actuator 1300 is in the inactive state having no voltage applied. On the application of a voltage across electrode beam 1302 and electrode 1304, actuator 1300 enters the first stage. Referring to FIG. 14, a schematic view of an actuator 1300 is illustrated positioned at the end of the first stage of the two-stage mode of actuation. Actuator 1300 enters the first stage when a sufficient voltage is applied across electrode beam 1302 and electrode 1304. As described above, an attractive force results and electrode beam 1302 is bent along the contour of curved surface 1400. As shown, due to the displacement of extension arm 1316 in a direction x 1312, electrode beam 1306 and frame 1310 are moved a distance d3 1402 that curved surface 1400 extends in direction x 1312. Because electrode beam 1306 is moved in a direction x 1312 to a position closer to electrode 1308, a smaller voltage applied across electrode beam 1306 and electrode 1308 to move electrode beam 1306.

The movement of electrode beam 1306 to curved surface 1404 of electrode 1308 begins the second stage of actuation. Referring now to FIG. 15, a schematic view of actuator 1300 is illustrated positioned at the end of the second stage of actuation. Actuator 1300 enters the second stage at the end of the first stage, after electrode beam 1302 has bent along the contour of curved surface 1400. At this point, electrode beam 1306 is positioned close enough to electrode 1308 such that an applied voltage between them bend electrode beam 1306 along the contour of curved surface 1404. As a result of the second stage of actuation, frame 1310 is displaced in a direction x 1312 by a distance d4 1500, the distance curved surface 1404 extends in a direction x 1312. Therefore, as a result of the first and second stages, frame 1310 is displaced a total distance of distance d3 1402 plus distance d4 1500 in a direction x 1312 from its position in the inactive state.

Alternatively, any type of flexure or other connection as described above can be used for connecting electrode beam 1306 to frame 1310. Simulation results of a two-stage actuator employing one-fold flexures with each of distances d3 1402 and d4 1500 set to 50 micrometers and an applied voltage of 140 volts produced a frame displacement of 85.5 micrometers.

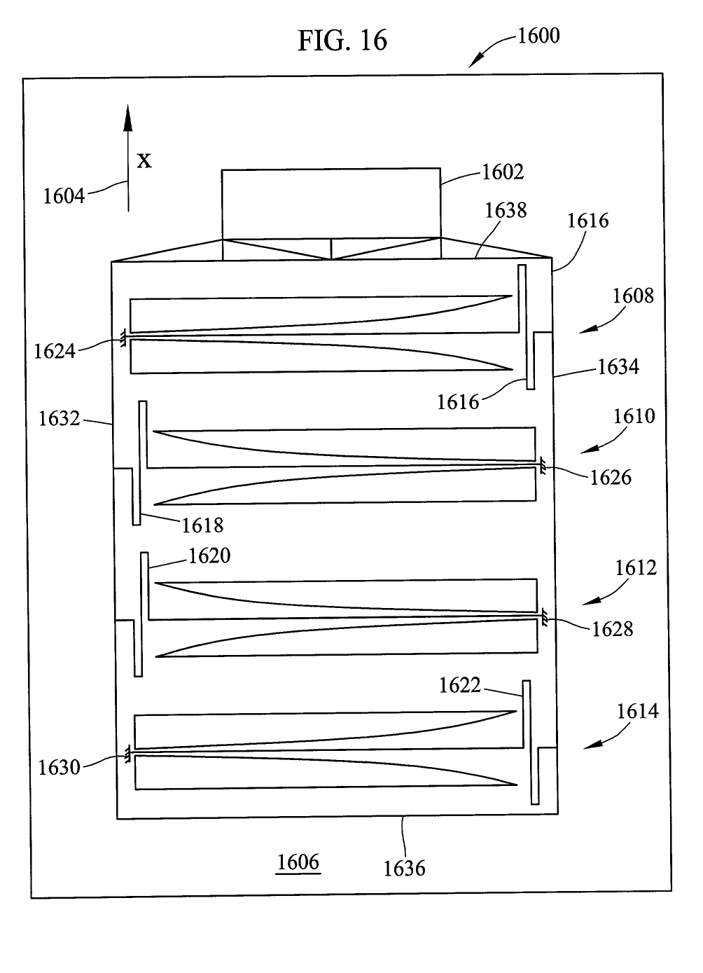

Several different frame structures and actuator configurations can be implemented. Referring to FIG. 16, a schematic view of another embodiment of a MEMS device according to this invention and generally designated 1600 is illustrated for moving a shutter 1602 in a linear direction x 1604 in a plane parallel to the plane of a substrate surface 1606. MEMS device 1600 includes bidirectional actuators generally designated 1608, 1610, 1612, and 1614 for moving frame and attached shutter 1602 in a direction x 1604 and opposite direction x 1604. Actuators 1608,1610,1612, and 1614 are attached to frame 1616 via flexures 1616,1618,1620, and 1622, respectively. Actuators 1608, 1610, 1612, and 1614 are connected to substrate surface 1606 via anchors 1624, 1626,1628, and 1630, respectively.

Frame 1616 is considered a “framed” structure which surrounds actuators 1608,1610, 1612, and 1614. Frame 1616 consists of arms 1632, 1634,1636, and 1638 for providing attachment to actuators 1608,1610,1612, and 1614 and shutter 1602. Arm 1632 attaches frame 1616 to actuators 1610 and 1612. Arm 1634 attaches frame 1616 to actuators 1608 and 1614. Arms 1636 and 1638 connects arm 1632 to arm 1634. Additionally, arm 1638 is attached to shutter 1602.

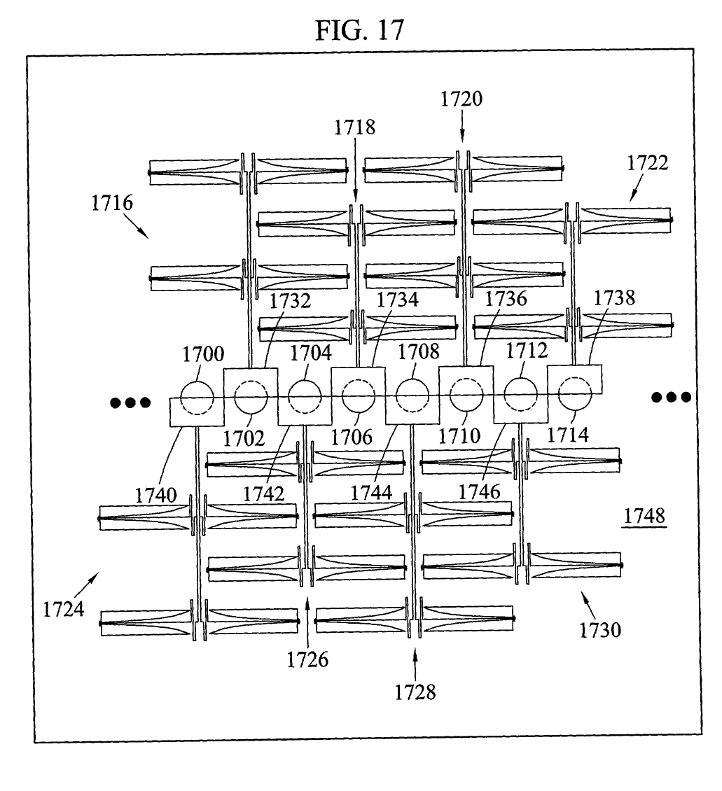

Optical MEMS devices employing bidirectional actuators can be closely placed together for economizing substrate surface space. Referring to FIG. 17, a schematic view of a set of light pathways 1700,1702,1704,1706,1708,1710, 1712, and 1714 extending perpendicular to the substrate and a set of bi-directional actuators generally designated 1716, 1718,1720,1722,1724, 1726, 1728, and 1730 is illustrated. Actuators 1716, 1718, 1720, 1722, 1724, 1726, 1728, and 1730 include shutters 1732,1734,1736,1738,1740,1742,1744, and 1746, respectively, for interacting with light pathways 1702,1706, 1710, 1714, 1700,1704, and 1712, respectively. As shown, actuators 1716,1718,1720, and 1722 are aligned along one side of light pathways 1700, 1702, 1704, 1706, 1708, 1710, 1712, and 1714 in an opposing position to actuators 1724,1726, 1728, and 1730 in order to conserve the space on surface 1748 of the substrate. Additionally, as shown, the actuators comprising each actuator 1716, 1718, 1720,1722,1724,1726,1728, and 1730 are interleaved in order to conserve the space on substrate surface 1748.

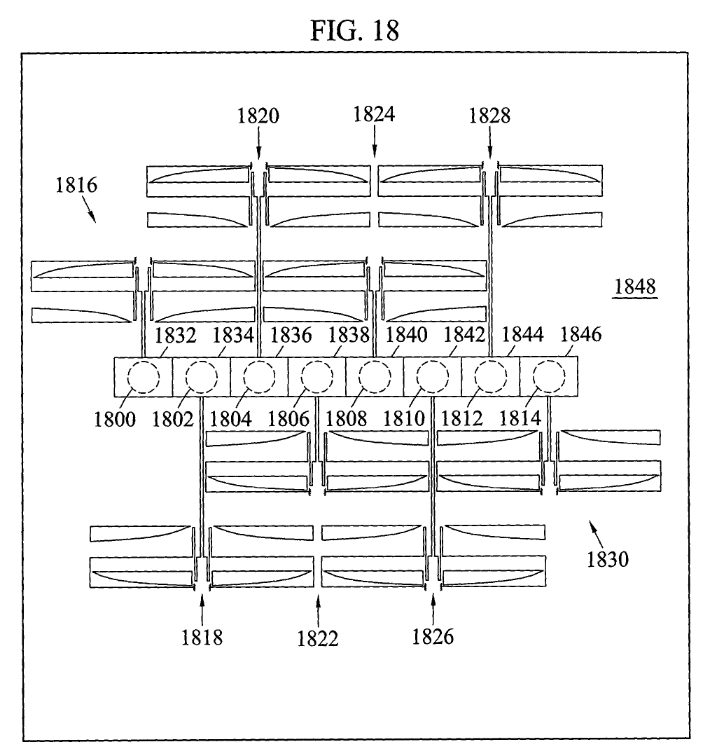

Referring to FIG. 18, a schematic view of another set of light pathways 1800,1802,1804,1806,1808,1810,1812, and 1814 extending perpendicular to a substrate and a set of unidirectional, two-stage actuators generally designated 1816,1818,1820,1822, 1824, 1826,1828, and 1830 is illustrated. Actuators 1816, 1818, 1820, 1822, 1824, 1826, 1828, and 1830 include shutters 1832, 1834,1836,1838,1840, 1842,1844, and 1846, respectively, for interacting with light pathways 1802,1804,1806,1808,1810,1812, and 1814, respectively. As shown, actuators 1816,1820,1822,1824, and 1828 are aligned along one side of light pathways 1802,1804,1806,1808,1810,1812, and 1814 in an opposing position to actuators 1818,1822,1826, and 1830 in order to conserve the space on surface 1848 of the substrate. Additionally, as shown, the actuators comprising each actuator 1816,1818,1820,1822,1824,1826,1828, and 1830 are interleaved in order to conserve the space on substrate surface 1848.

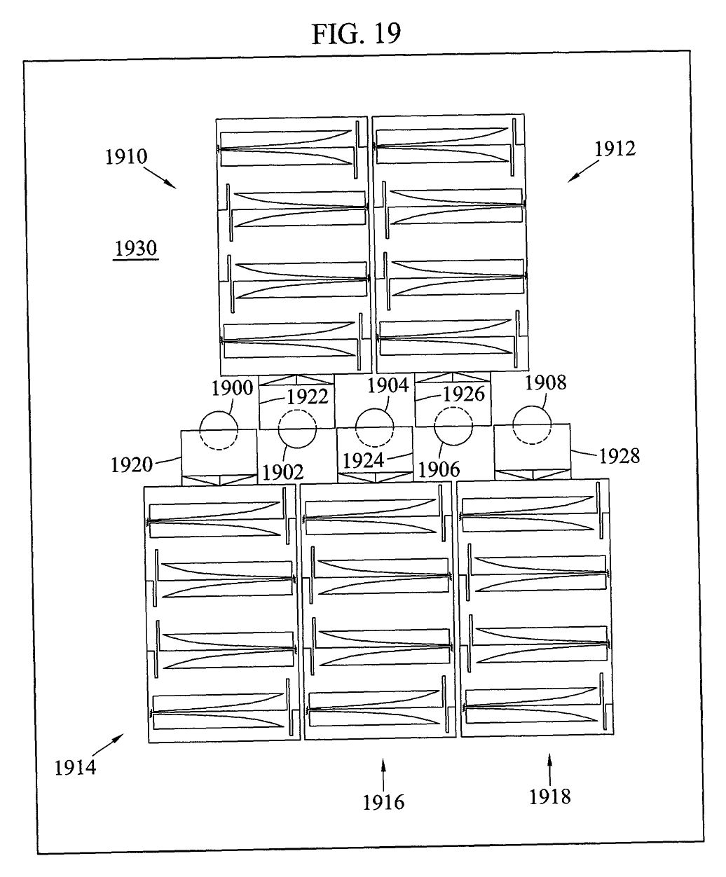

Referring to FIG. 19, a schematic view of another set of light pathways 1900,1902, 1904,1906, and 1908 extending perpendicular to a substrate and a set of framed, bi-directional actuators generally designated 1910, 1912, 1914, 1916, and 1918 is illustated. Actuators 1910, 1912, 1914, 1916, and 1918 include shutters 1920,1922,1924,1926, and 1928, respectively, for interacting with light pathways 1900,1902,1904,1906, and 1908, respectively. As shown, actuators 1910 and 1912 are aligned along one side of light pathways 1900, 1902, 1904, 1906, and 1908 in an opposing position to actuators 1914,1916, and 1918 in order to conserve the space on surface 1930 of the substrate.

Although the present invention has been described with respect to the use of MEMS device for moving shutters in a linear direction along the plane of a substrate surface, the principles of the present invention also can be used for many other applications requiring actuation. Furthermore, it will be understood that various details of the invention can be changed without departing from the scope of the invention. The foregoing description is for the purpose of illustration only, and not for the purpose of limitation - the invention being defined by the claims.

What is claimed is:

1. An actuator, comprising:
(a) a substrate having a surface;
(b) an actuating device movable in a substantially linear direction with respect to the substrate;
(c) at least one bendable electrode beam attached to the actuating device and having an end attached to the substrate, the electrode beam being flexible between the actuating device and the end of the electrode beam attached to the substrate; and
(d) at least one electrode attached to the substrate, the electrode having a curved surface aligned in a position adjacent the length of the electrode beam, whereby the actuating device is movable in the substantially linear direction as the electrode beam moves in a curved fashion corresponding substantially to the curved surface of the electrode.

2. The actuator of claim 1 wherein the actuating device includes an optical component for interacting with light transmitted along a light pathway.

3. The actuator of claim 2 wherein the optical component is a shutter.

4. The actuator of claim 1 wherein the electrode beam is attached to the substrate via an anchor.

5. The actuator of claim 1 wherein the electrode beam includes a flexure portion attached between the actuating device and the end of the electrode beam attached to the substrate.

6. The actuator of claim 5 wherein the flexure portion is a two-fold flexure.

7. The actuator of claim 5 wherein the flexure portion is a one-fold flexure.

8. The actuator of claim 5 wherein the flexure portion is a crab leg flexure.

9. The actuator of claim 1 wherein the electrode beam is substantially straight and positioned substantially perpendicular to the linear direction.

10. The actuator of claim 1 wherein a first position along the length of the curved surface is closer to the electrode beam than a second position along the length of the curved surface that is closer to the actuating device.

11. The actuator of claim 1 wherein the maximum distance separating the curved surface and the electrode beam is between 35 and 50 micrometers.

12. The actuator of claim 1 wherein the at least one electrode beam includes a first and second electrode beam, the first electrode beam attached to actuating device on a first side, the second electrode beam attached to actuating device on a second side that opposes the first side for translating motion of the curved electrode in the substantially linear direction.

13. The actuator of claim 1 further including at least one electrically-isolated bumper attached to the substrate at a position in the path of movement between the electrode beam and the electrode for preventing the electrode beam and the electrode from shunting.

14. An actuator, comprising:
(a) a substrate having a surface;
(b) an actuating device movable in a substantially linear first direction and a substantially linear second direction with respect to the substrate;
(c) at least one bendable electrode beam attached to the actuating device and having an end attached to the substrate, the electrode beam being flexible between the actuating device and the end of the electrode beam attached to the substrate;
(d) at least one first electrode attached to the substrate, the electrode having a curved surface aligned in a position adjacent the length of the electrode beam, whereby the actuating device is movable in its substantially linear first direction as the electrode beam moves in a curved fashion corresponding substantially to the curved surface of the first electrode; and
(e) at least one second electrode attached to the substrate, the electrode having a curved surface aligned in a position adjacent the length of the electrode beam, whereby the actuating device is movable in its substantially linear second direction as the electrode beam moves in a curved fashion corresponding substantially to the curved surface of the first electrode.

15. The actuator of claim 14 wherein the actuating device includes an optical component for interacting with light transmitted along a light pathway substantially perpendicular to the first and second linear directions.

16. The actuator of claim 14 wherein the optical component is a shutter.

17. The actuator of claim 14 wherein the electrode beam includes a flexure portion.

18. The actuator of claim 17 wherein the flexure portion is a two-fold flexure.

19. The actuator of claim 17 wherein the electrode beam is substantially straight and positioned substantially perpendicular to the first and second direction.

20. The actuator of claim 17 wherein a first position along the length of the curved surface of the first electrode is closer to the electrode beam than a second position along the length of the curved surface of the first electrode that is closer to the actuating device.

21. The actuator of claim 14 wherein a first position along the length of the curved surface of the second electrode is closer to the electrode beam than a second position along the length of the curved surface of the second electrode that is closer to the actuating device.

22. The actuator of claim 14 wherein the at least one electrode beam includes at least two electrode beams.

23. An actuator, comprising:
(a) a substrate having a surface;
(b) an actuating device movable in a substantially linear direction with respect to the substrate;
(c) at least one bendable first electrode beam having an end attached to the substrate;
(d) at least one bendable second electrode beam attached to the first electrode beam and having an end attached to the actuating device, the electrode beam being flexible between the actuating device and the end of the electrode beam attached to the first electrode beam;
(e) at least one first electrode attached to the substrate, the electrode having a curved surface aligned in a position adjacent the length of the first electrode beam, whereby the actuating device is movable in its substantially linear direction as the first electrode beam moves in a curved fashion corresponding substantially to the curved surface of the first electrode;
(f) at least one second electrode attached to the substrate, the electrode having a curved surface aligned in a position adjacent the length of the second electrode beam, whereby the actuating device is movable in its substantially linear direction as the second electrode beam moves in a curved fashion corresponding substantially to the curved surface of the second electrode after the first electrode beam moves in a curved fashion corresponding substantially to the curved surface of the first electrode.

24. A method for moving an actuating device in a linear direction, comprising:
(a) providing a substrate having a surface;
(b) providing an actuating device movable in a substantially linear direction with respect to the substrate;
(c) providing at least one bendable electrode beam attached to the actuating device and having an end attached to the substrate, the electrode beam being flexible between the actuating device and the end of the electrode beam attached to the substrate;
(d) providing at least one electrode attached to the substrate, the electrode having a curved surface aligned in a position adjacent the length of the electrode beam; and
(e) applying a voltage across the electrode beam and curved electrode to move the electrode beam in a curved fashion corresponding to the curved surface of the electrode, whereby the actuating device moves in a substantially linear direction.

25. The method of claim 24 wherein the electrode beam includes a flexure portion attached between the actuating device and the end of the electrode beam attached to the substrate.
